(19) United States
(12) Patent Application Publication
(10) Pub. No.: US 2025/0191992 A1
(43) Pub. Date: Jun. 12, 2025

(54) COOLING DEVICE, HEAT DISSIPATION MEMBER, AND SEMICONDUCTOR MODULE

(71) Applicant: NIDEC CORPORATION, Kyoto (JP)

(72) Inventors: Kazuhiro NISHIKAWA, Kyoto (JP); Masaaki HANANO, Kyoto (JP); Koji MURAKAMI, Kyoto (JP); Yuta HORI, Kyoto (JP)

(21) Appl. No.: 18/843,702

(22) PCT Filed: Mar. 2, 2023
(86) PCT No.: PCT/JP2023/007826

§ 371 Date: Sep. 4, 2024

(30) Foreign Application Priority Data
Mar. 7, 2022 (JP) 2022-034360

(51) Int. Cl. H01L 23/367; H01L 23/473

(52) U.S. Cl. CPC H01L 23/367; H01L 23/473

(57) ABSTRACT

A cooling device includes a liquid cooling jacket and a heat dissipation member. The heat dissipation member includes a base extending in a first direction of a refrigerant flow and in a second direction, with a thickness in a third direction, a fin projecting from the base to one side in the third direction, and a top plate at an end of the fin. The jacket includes a first flow path extending in the first direction, and a second flow path connected to and extending from the downstream side of the first path to one side in the third direction. In the third direction, a surface connecting the first and second paths overlaps the top plate. A heating element is on the most downstream side on another side in the third direction of the base from where the second path starts to extend to one side in the third direction.

### TECHNICAL FIELD

The present disclosure relates to a cooling device, a heat dissipation member, and a semiconductor module.

### BACKGROUND ART

Conventionally, a cooling device is used for cooling a heating element. A cooling device includes a heat dissipation member and a liquid cooling jacket. The heat dissipation member includes a base portion and a plurality of fins. A plurality of the fins project from the base portion. A flow path is formed by the heat dissipation member and the liquid cooling jacket. When a refrigerant flows through the flow path, heat of a heating element moves to the refrigerant (see, for example, Patent Literature 1).

### CITATIONS LIST

### Patent Literature

Patent Literature 1: WO 2013/157467 A

### SUMMARY OF INVENTION

### Technical Problems

In the conventional cooling device, there is a case where a plurality of heating elements are arranged on the base portion along a direction in which a refrigerant flows in the flow path. In this case, there is a possibility that cooling performance of a heating element arranged on the most downstream side is insufficient depending on a shape of the flow path based on the liquid cooling jacket.

In view of the above circumstances, an object of the present disclosure is to provide a cooling device and the like capable of improving cooling performance of a heating element arranged on the most downstream side.

### Solutions to Problems

An exemplary cooling device of the present disclosure includes a liquid cooling jacket and a heat dissipation member installed in the liquid cooling jacket. The heat dissipation member includes a plate-shaped base portion that extends in a first direction along a direction in which a refrigerant flows and in a second direction orthogonal to the first direction and has thickness in a third direction orthogonal to the first direction and the second direction, at least one fin that projects from the base portion to one side in the third direction, and a top plate portion provided in an end portion on one side in the third direction of the at least one fin. The liquid cooling jacket includes a first flow path extending in the first direction in which the fin and the top plate portion are arranged, and a second flow path connected to the downstream side of the first flow path and extending from the first flow path to one side in the third direction. When viewed in the third direction, a connection surface that connects the second flow path and the first flow path overlaps the top plate portion. A heating element is arranged on the most downstream side on another side in the third direction of the base portion from a position where the second flow path starts to extend to one side in the third direction.

Further, an exemplary cooling device of the present disclosure is a cooling device including a liquid cooling jacket and a heat dissipation member. The heat dissipation member includes a plate-shaped base portion that extends in a first direction along a direction in which a refrigerant flows and in a second direction orthogonal to the first direction, and has thickness in a third direction orthogonal to the first direction and the second direction, at least one fin projecting from one surface of the base portion to one side in the third direction, and a top plate portion provided in an end portion on one side in the third direction of the at least one fin. A heating element is arranged on another surface of the base portion. The refrigerant flows from another side in the first direction to one side in the first direction through a flow path including the liquid cooling jacket and the heat dissipation member. Depth of the liquid cooling jacket increases in the third direction in a facing region facing the heating element in the third direction in a downstream side region of the flow path. The top plate portion is provided in at least a part of the facing region.

Further, an exemplary heat dissipation member of the present disclosure is a heat dissipation member installed in a liquid cooling jacket, the heat dissipation member including a plate-shaped base portion that extends in a first direction along a direction in which a refrigerant flows and in a second direction orthogonal to the first direction, and has thickness in a third direction orthogonal to the first direction and the second direction, at least one fin projecting from the base portion to one side in the third direction, and a top plate portion provided in an end portion on one side in the third direction of the at least one fin. The liquid cooling jacket includes a first flow path extending in the first direction in which the fin and the top plate portion are arranged, and a second flow path connected to the downstream side of the first flow path and extending from the first flow path to one side in the third direction. When viewed in the third direction, a connection surface that connects the second flow path and the first flow path overlaps the top plate portion. A heating element is arranged on the most downstream side on another side in the third direction of the base portion from a position where the second flow path starts to extend to one side in the third direction.

### Advantageous Effects of Invention

According to the exemplary cooling device and the like of the present disclosure, cooling performance of the heating element arranged on the most downstream side can be improved.

### BRIEF DESCRIPTION OF DRAWINGS

FIG. 1 is an exploded perspective view of a cooling device according to an exemplary embodiment of the present disclosure.

FIG. 2 is a side cross-sectional view of the cooling device according to the exemplary embodiment of the present disclosure.

FIG. 3 is a perspective view of a heat dissipation member according to the exemplary embodiment of the present disclosure.

FIG. 4 is a perspective view of a first fin.

FIG. 5 is a perspective view of a second fin.

FIG. 6 is a partial side cross-sectional view of a cooling device according to a comparative example.

FIG. 7 is a partial side cross-sectional view illustrating a configuration on the most downstream side in the cooling device according to the exemplary embodiment of the present disclosure.

FIG. 8A is a graph illustrating an example of a simulation result of a first simulation.

FIG. 8B is a graph illustrating an example of a simulation result of the first simulation.

FIG. 8C is a graph illustrating an example of a simulation result of the first simulation.

FIG. 8D is a graph illustrating an example of a simulation result of the first simulation.

FIG. 9 is a partial side cross-sectional view of the cooling device used in a second simulation.

FIG. 10 is a graph illustrating an example of a simulation result of the second simulation.

FIG. 11 is a perspective view illustrating a configuration example of the heat dissipation member using a pin fin.

FIG. 12 is an enlarged perspective view illustrating a configuration example of a single spoiler.

### DESCRIPTION OF EMBODIMENTS

Hereinafter, an exemplary embodiment of the present disclosure will be described with reference to the drawings.

Note that, in the drawings, with a first direction as an X direction, X1 indicates one side in the first direction, and X2 indicates another side in the first direction. The first direction is along a direction F in which a refrigerant WT flows, and F1 indicates the downstream side and F2 indicates the upstream side. With a second direction orthogonal to the first direction as a Y direction, Y1 indicates one side in the second direction, and Y2 indicates another side in the second direction. With a third direction orthogonal to the first direction and the second direction as a Z direction, Z1 indicates one side in the third direction, and Z2 indicates another side in the third direction. Note that the above-described “orthogonal” also includes intersection at an angle slightly shifted from 90°. The above-described directions do not limit a direction when a cooling device 150 and a heat dissipation member 1 are incorporated in various devices.

### <1. Configuration of Cooling Device>

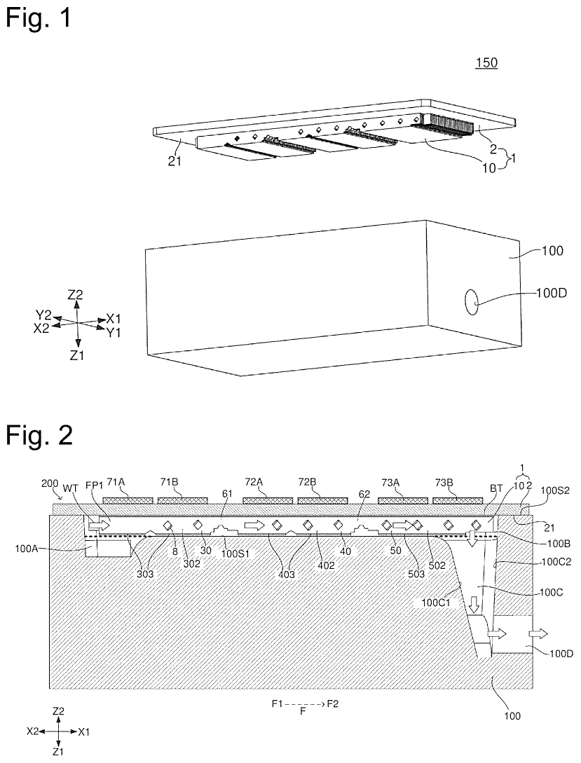

FIG. 1 is an exploded perspective view of the cooling device 150 according to an exemplary embodiment of the present disclosure. FIG. 2 is a side cross-sectional view of the cooling device 150. FIG. 2 is a diagram of the cooling device 150 taken along a cross section orthogonal to the second direction at an intermediate position in the second direction and viewed from another side in the second direction toward one side in the second direction.

The cooling device 150 includes a liquid cooling jacket 100 and the heat dissipation member 1 installed in the liquid cooling jacket 100. Note that FIG. 2 illustrates flow of the refrigerant WT. One side in the first direction is the downstream side in a direction in which the refrigerant WT flows, and another side in the first direction is the upstream side in a direction in which the refrigerant WT flows. The refrigerant WT is liquid such as water.

The cooling device 150 is a device for cooling a plurality of semiconductor devices 71A, 71B, 72A, 72B, 73A, and 73B (hereinafter, 71A and the like). The semiconductor device is an example of a heating element. The semiconductor devices 71A and the like are power transistors of an inverter included in a traction motor for driving a wheel of a vehicle, for example. The power transistor is, for example, an insulated gate bipolar transistor (IGBT). In this case, the cooling device 150 is mounted on the traction motor. Note that the number of semiconductor devices may be more than one other than six.

The heat dissipation member 1 includes a heat dissipation fin portion 10 and a base portion 2. The heat dissipation fin portion 10 is fixed to one side in the third direction with respect to the base portion 2. The liquid cooling jacket 100 includes an inlet flow path 100A, a first flow path 100B (a space on another side in the third direction from a broken line in FIG. 2), a second flow path 100C, and an outlet flow path 100D.

The inlet flow path 100A is arranged on another side in the first direction in the liquid cooling jacket 100. The first flow path 100B extends in the first direction. Another end in the first direction of the first flow path 100B is arranged further on another side in the third direction than the inlet flow path 100A, and is connected to the inlet flow path 100A in the third direction.

The second flow path 100C is arranged on one side in the first direction in the liquid cooling jacket 100 and extends in the third direction. Note that the second flow path 100C includes a first inclined wall 100C1 that is inclined to one side in the first direction and one side in the third direction, and a second inclined wall 100C2 that is perpendicular to the first direction and extends along the third direction. That is, the second flow path 100C includes the first inclined wall 100C1 extending in a direction including a first direction component and a third direction component in addition to the second inclined wall 100C2 extending in the third direction not including the first direction component. Also in such a case, it can be said that the second flow path 100C extends in the third direction.

Note that the second flow path 100C may have the second inclined wall 100C2 inclined to another side in the first direction and one side in the third direction. That is, assuming that the downstream side where the refrigerant WT flows is one side in the first direction, the second flow path 100C only needs to have at least one of the first inclined wall 100C1 inclined to one side in the first direction and one side in the third direction and the second inclined wall 100C2 inclined to another side in the first direction and one side in the third direction. By the above, in a case where the liquid cooling jacket 100 is manufactured by casting to form the second flow path 100C, a mold can be easily removed.

An end portion on one side in the first direction of the first flow path 100B is arranged further on another side in the third direction than the second flow path 100C, and is connected to the second flow path 100C in the third direction. The outlet flow path 100D is arranged at an end portion on one side in the first direction in the liquid cooling jacket 100 and extends in the first direction. An end portion on one side in the third direction of the second flow path 100C is connected to the outlet flow path 100D. The outlet flow path 100D opens toward one side in the first direction of the liquid cooling jacket 100 (see FIG. 1).

In the liquid cooling jacket 100, a top surface 100S1 is formed at an end on one side in the third direction of the first flow path 100B. The top surface 100S1 is a flat surface extending in the first direction and the second direction.

In a state where the heat dissipation member 1 is not attached to the liquid cooling jacket 100, the top surface 100S1 is exposed to another side in the third direction. The heat dissipation member 1 is attached to the liquid cooling jacket 100 by fixing a surface 21 on one side in the third direction of the base portion 2 in the heat dissipation member 1 to a surface 100S2 on another side in the third direction of the liquid cooling jacket 100. In a state where the heat dissipation member 1 is attached, another side in the third direction of the top surface 100S1 is covered with the base portion 2. By the above, the first flow path 100B is closed by the base portion 2.

In a state the heat dissipation member 1 is attached to the liquid cooling jacket 100, the heat dissipation fin portion 10 is arranged inside the first flow path 100B. The heat dissipation fin portion 10 is constituted by stacking a plurality of fins FP in the second direction as described later. The fin FP has a top plate portion 503 as described later. That is, the fin FP and the top plate portion 503 are arranged in the first flow path 100B.

The refrigerant WT having flowed from the outside of the liquid cooling jacket 100 into the inlet flow path 100A flows through the inlet flow path 100A and then flows into the first flow path 100B. The refrigerant WT flowing through the first flow path 100B toward one side in the first direction flows into the second flow path 100C. The refrigerant WT flowing through the second flow path 100C toward one side in the third direction flows into the outlet flow path 100D and is discharged to the outside of the liquid cooling jacket 100. That is, the refrigerant WT flows from another side in the first direction to one side in the first direction through a flow path (a flow path including the first flow path 100B and the second flow path 100C) constituted by the liquid cooling jacket 100 and the heat dissipation member 1.

The semiconductor devices 71A and the like are arranged on another side in the third direction of the base portion 2. That is, heating elements (71A and the like) are arranged on another surface of the base portion 2. Heat generated from the semiconductor devices 71A and the like moves from the heat dissipation fin portion 10 to the refrigerant WT flowing inside the first flow path 100B, so that the semiconductor devices 71A and the like are cooled. Note that a semiconductor module 200 is constituted by the semiconductor devices 71A and the like and the heat dissipation member 1. That is, the semiconductor module 200 includes the heat dissipation member 1 and the semiconductor device 73B as a heating element.

In other words, the liquid cooling jacket 100 includes the first flow path 100B in which the fin FP and the top plate portion 503 can be arranged and which extends in the first direction, and the second flow path 100C connected to the downstream side with respect to the first flow path 100B and extending from the first flow path 100B to one side in the third direction.

### <2. Overall Configuration of Heat Dissipation Member>

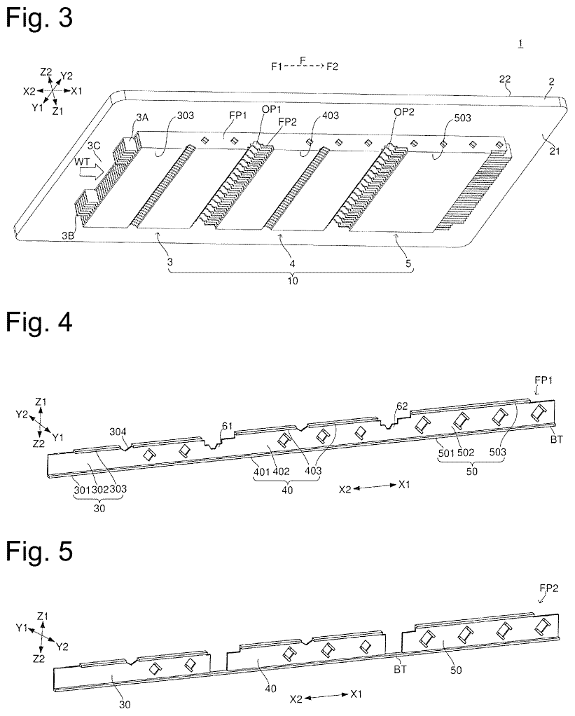

Next, the heat dissipation member 1 will be described in more detail. FIG. 3 is a perspective view of the heat dissipation member 1 according to the exemplary embodiment of the present disclosure.

As described above, the heat dissipation member 1 can be installed in the liquid cooling jacket 100, and includes the base portion 2 and the heat dissipation fin portion 10. The heat dissipation fin portion 10 includes an upstream side fin group 3, a center fin group 4, and a downstream side fin group 5.

The base portion 2 has a plate shape that extends in the first direction and the second direction and has thickness in the third direction. The base portion 2 is made from metal having high thermal conductivity, such as a copper alloy.

The upstream side fin group 3, the center fin group 4, and the downstream side fin group 5 (hereinafter, the fin groups 3, 4, and 5) are arranged on one side in the third direction of the base portion 2 from another side (upstream side) in the first direction toward one side (downstream side) in the first direction in this order. As described later, the fin groups 3, 4, and 5 are fixed to the surface 21 on one side in the third direction of the base portion 2 by brazing, for example.

The semiconductor devices 71A and the like (FIG. 2) are directly or indirectly fixed to a surface 22 on another side in the third direction of the base portion 2. When viewed in the third direction, the heating elements 71A and 71B overlap the upstream side fin group 3, the heating elements 72A and 72B overlap the center fin group 4, and the heating elements 73A and 73B overlap the downstream side fin group 5.

When the refrigerant WT is supplied to the upstream side fin group 3 from the upstream side further than the upstream side fin group 3, the refrigerant WT sequentially flows through the fin groups 3, 4, and 5 in this order and is discharged from the downstream side fin group 5 to the downstream side. At this time, heat generated from the semiconductor devices 71A and the like moves to the refrigerant WT via the base portion 2 and the fin groups 3, 4, and 5. By the above, the semiconductor devices 71A and the like are cooled.

### <3. Method of Forming Fin Group>

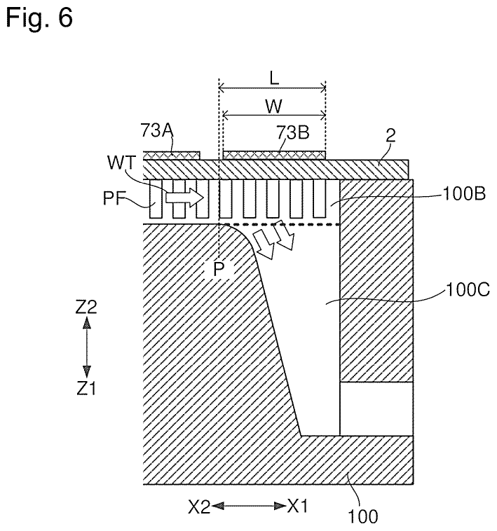

Here, an example of a specific method of forming the heat dissipation fin portion 10 (fin groups 3, 4, and 5) will be described also with reference to FIGS. 5 and 6.

The heat dissipation fin portion 10 is configured as what is called a stacked fin by arranging a plurality of fins (fin plates) FP in the second direction. The fin FP is constituted by a metal plate extending in the first direction, and constituted by a copper plate, for example. Note that each of fins FP1 and FP2 illustrated in the diagram is a kind of the fin FP. That is, FP is used as a general reference sign of a fin.

FIG. 4 is a perspective view of the first fin FP1. The first fin FP1 includes an upstream side fin portion 30, a center fin portion 40, and a downstream side fin portion 50 (hereinafter, fin portions 30, 40, and 50). The fins 30, 40, and 50 constitute the fin groups 3, 4, and 5, respectively.

The upstream side fin portion 30 includes a bottom plate portion 301, a side wall portion 302, and a top plate portion 303. The side wall portion 302 has a plate shape extending in the first direction and the third direction and having a thickness direction in the second direction. The bottom plate portion 301 is formed by being bent from an end portion on another side in the third direction of the side wall portion 302 to one side in the second direction. The top plate portion 303 is formed by being bent from an end portion on one side in the third direction of the side wall portion 302 to another side in the second direction. Note that the top plate portion 303 is provided to be divided into one side in the first direction and another side in the first direction of a notch portion 304. The notch portion 304 has a shape notched from an end on one side in the third direction of the side wall portion 302 toward another side in the third direction. The bottom plate portion 301 and the top plate portion 303 face each other in the third direction. Due to this, the upstream side fin portion 30 has a rectangular U-shaped cross section in a cross section orthogonal to the first direction.

Note that the bottom plate portion 301 and bottom plate portions 401 and 501 described later are a part of a bottom plate portion BT extending over an entire length in the first direction of the first fin FP1.

The center fin portion 40 includes the bottom plate portion 401, a side wall portion 402, and a top plate portion 403. The downstream side fin portion 50 includes the bottom plate portion 501, a side wall portion 502, and a top plate portion 503. A configuration of the center fin portion 40 and the downstream side fin portion 50 is basically similar to that of the upstream side fin portion 30 described above, and thus, omitted from detailed description here. However, as illustrated in FIG. 4, the top plate portion 503 of the downstream side fin portion 50 is not divided in the first direction.

A coupling fin 61 is arranged between the upstream side fin portion 30 and the center fin portion 40. The coupling fin 61 couples the fin portions 30 and 40 in the first direction. The coupling fin 62 is arranged between the center fin portion 40 and the downstream side fin portion 50. The coupling fin 62 couples the fin portions 40 and 50 in the first direction.

FIG. 5 is a perspective view of the second fin FP2. A difference in configuration between the second fin FP2 and the first fin FP1 is that only a part of the bottom plate portion BT is arranged without the coupling fin 61 being arranged between the upstream side fin portion 30 and the center fin portion 40, and only a part of the bottom plate portion BT is arranged without the coupling fin 62 being arranged between the center fin portion 40 and the downstream side fin portion 50.

That is, the fin FP includes a flat plate-shaped side wall portion (a flat plate portion including the side wall portions 302, 402, and 502) that extends in the first direction and the third direction and has thickness in the second direction, and the top plate portion 503 that is formed to be bent in the second direction in an end portion on one side in the third direction of the side wall portion. By the above, since the top plate portion 503 can be formed by press working, the top plate portion 503 can be easily manufactured.

As illustrated in FIG. 3, the heat dissipation fin portion 10 is configured by alternately arranging the first fin FP1 and the second fin FP2 in the second direction. However, some of the fins FP1 and FP2 are formed to extend to another side in the first direction or one side in the first direction. The fins FP1 and FP2 extended to another side in the first direction constitute end portion fin groups 3A and 3B (see FIG. 3). Between the end portion fin groups 3A and 3B, 3C recessed to another side in the third direction is formed. By checking the recessed portion 3C, a worker can prevent an attachment direction error when attaching the heat dissipation member 1.

As described above, the heat dissipation fin portion 10 (fin groups 3, 4, and 5) is formed with various types of the fin FP arranged in the second direction and integrated by, for example, riveting or the like. The formed heat dissipation fin portion 10 is fixed to the surface 21 on one side in the third direction of the base portion 2 by brazing, for example. As described above, by constituting the heat dissipation fin portion 10 using the fin FP having a configuration in which the fin portions 30, 40, and 50 are integrated in the first direction, it is possible to increase rigidity of the heat dissipation member 1 and prevent deflection and the like due to flow of the refrigerant WT in a case where thickness of the base portion 2 is reduced for thermal conductivity.

That is, the heat dissipation member 1 includes at least one of the fins FP projecting from the base portion 2 to one side in the third direction, and the top plate portion 503 provided at an end portion on one side in the third direction of the at least one of the fins FP. It can also be said that the at least one of the fins FP projects from one surface of the base portion 2 to one side in the third direction.

### <4. Flow of Refrigerant>

Flow of the refrigerant WT in the heat dissipation member 1 having such a configuration will be described with reference to FIG. 2. In FIG. 2, flow of the refrigerant WT is indicated by an arrow. Note that, in FIG. 2, the first fin FP1 is illustrated in a state where a cross section is viewed from another side in the second direction. The bottom plate portion BT and the top plate portions 303, 403, and 503 illustrated in FIG. 2 are configured to be included in the second fin FP2 (not illustrated) adjacent to another side in the second direction (the front side in the diagram) of the first fin FP1.

In the fin groups 3, 4, and 5, the refrigerant WT flows through a flow path formed between the fin portions 30, 40, and 50 adjacent in the second direction. At this time, the refrigerant WT flows on the bottom plate portion BT. Note that, in a case where the fin plate FP is not provided with the bottom plate portion BT, the refrigerant WT flows on the base portion 2. The refrigerant WT is guided along a wall surface (a surface orthogonal to the second direction) of the side wall portion 302 of the upstream side fin portion 30. The refrigerant WT is guided along a wall surface of the side wall portion 402 of the center fin portion 40. The refrigerant WT is guided along a wall surface of the side wall portion 502 of the downstream side fin portion 50.

Here, flow of the refrigerant WT on the most downstream side in the first flow path 100B will be described in detail. FIG. 6 is a partial side cross-sectional view of a cooling device according to a comparative example for comparison with the present embodiment. FIG. 6 illustrates a configuration in the vicinity of the most downstream side of the first flow path 100B. Further, in the heat dissipation member illustrated in FIG. 6, a pin fin PF is used as a fin. A plurality of the pin fins PF projects in a columnar shape from the base portion 2 toward one side in the third direction. The pin fin PF is accommodated in the first flow path 100B.

In the case of the configuration as illustrated in FIG. 6, the refrigerant WT flowing between the pin fins PF to one side in the first direction flows from the first flow path 100B to one side in the third direction at the connection portion between the first flow path 100B and the second flow path 100C. By the above, an amount of the refrigerant WT flowing to an end portion on the downstream side of the first flow path 100B decreases. Therefore, cooling performance of the semiconductor device 73B arranged on another side in the third direction in the end portion on the downstream side is lowered. The semiconductor device 73B is arranged on the most downstream side among a plurality of the semiconductor devices 71A and the like arranged in the first direction. That is, there is a problem in cooling performance of a heating element on the most downstream side.

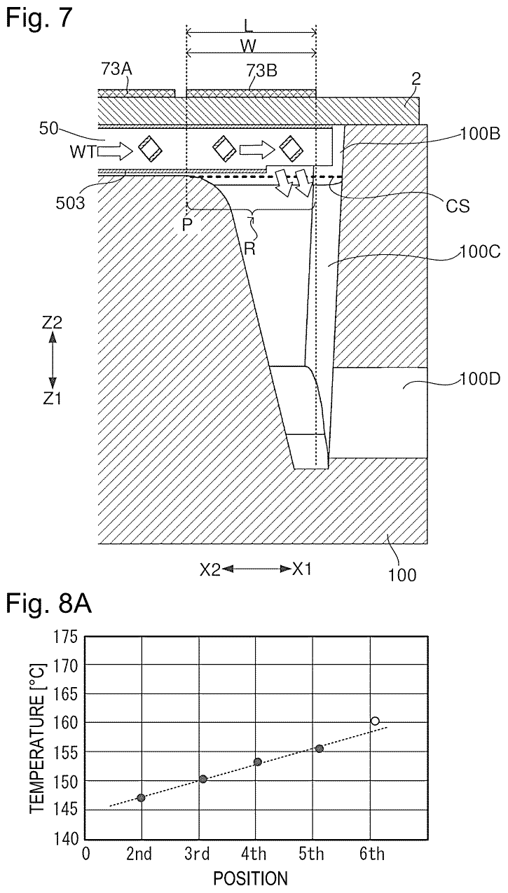

On the other hand, the present embodiment has a configuration as illustrated in FIG. 7. FIG. 7 is a partial side cross-sectional view illustrating a configuration on the most downstream side in the cooling device 150. In the example illustrated in FIG. 7, an end on another side in the first direction of the semiconductor device 73B is located at a position P where depth of the second flow path 100C starts to increase toward one side in the third direction. That is, a heating element (the semiconductor device 73B) is arranged on the most downstream side on another side in the third direction of the base portion 2 from the position P where the second flow path 100C starts to extend to one side in the third direction. Note that an end on another side in the first direction of the semiconductor device 73B may be located further on another side in the first direction or further on one side in the first direction than the position P. That is, at least a part of a heating element may be arranged further on one side in the first direction than the position P on another side in the third direction of the base portion 2.

Then, when viewed in the third direction, a connection surface CS connecting the second flow path 100C and the first flow path 100B overlaps the top plate portion 503. In the example illustrated in FIG. 7, the top plate portion 503 extends to another side in the first direction further than the connection surface CS, and a part of the top plate portion 503 overlaps the connection surface CS. Note that the entire top plate portion 503 may overlap the connection surface CS.

In other words, depth of the liquid cooling jacket 100 increases in the third direction in a facing region R facing, in the third direction, a heating element (semiconductor device 73B) in a downstream side region of the flow paths 100B and 100C, and the top plate portion 503 is provided in at least a part of the facing region R.

By providing the top plate portion 503 in this manner, it is possible to reduce an amount of the refrigerant WT flowing from a flow path formed between the fin portions 50 adjacent to each other in the second direction toward the second flow path 100C side and to increase an amount of the refrigerant WT flowing to an end portion on the downstream side of the first flow path 100B. By the above, cooling performance of the semiconductor device 73B can be improved. That is, cooling performance of a heating element arranged on the most downstream side can be improved. Further, according to the present configuration, a surface area of the fin portion 50 increases, and cooling performance can be improved.

<5. Condition Under which Cooling Performance is Effectively Exhibited>

Here, a condition under which cooling performance of a heating element (semiconductor device 73B) arranged on the most downstream side is more effectively exhibited will be described.

First, simulation below was performed on the cooling device using the pin fin PF not provided with a top plate portion as illustrated in FIG. 6. In the simulation, temperature of the semiconductor device 71A and the like was simulated by setting a first direction distance from the position P where the second flow path 100C starts to extend to one side in the third direction to a position of an end on the downstream side of the semiconductor device 73B to L, setting first direction width of a heating element to W, and changing a ratio calculated by (L/W)×100%. A condition of heat input by the semiconductor device was set to be constant.

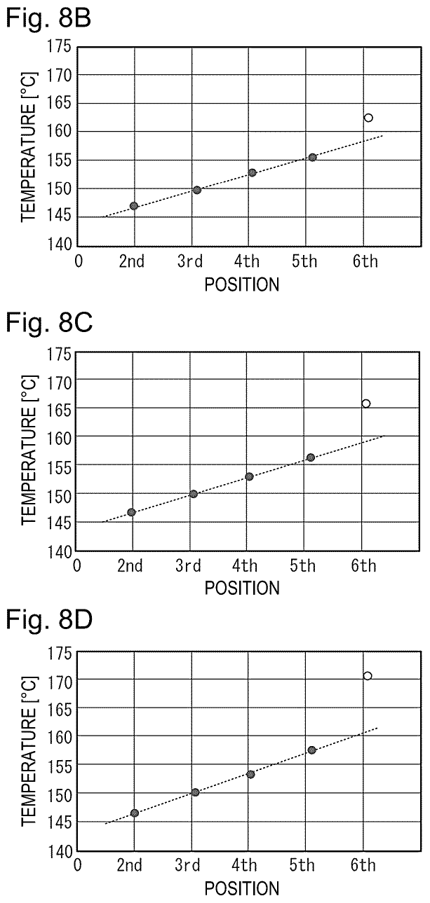

A result of the simulation is shown in graphs of FIGS. 8A, 8B, 8C, and 8D. In the graph, the horizontal axis indicates each position of the semiconductor devices 71A and the like. With a position of the semiconductor device 71A on the most upstream side at zero, a position of the second semiconductor device 71B is indicated as “2nd”, a position of the third semiconductor device 72A is indicated as “3rd”, a position of the fourth semiconductor device 72B is indicated as “4th”, a position of the fifth semiconductor device 73A is indicated as “5th”, and a position of the sixth semiconductor device 73B is indicated as “6th”. An interval between adjacent semiconductor devices is constant. Further, in the graph, the vertical axis represents temperature of a semiconductor device. Note that, in the above graph, temperature is plotted except for the semiconductor device 71A affected by inflow of a refrigerant from an inlet of a cooling device.

FIG. 8A illustrates a case where the calculated ratio is 25%, FIG. 8B illustrates a case where the calculated ratio is 50%, FIG. 8C illustrates a case where the calculated ratio is 75%, and FIG. 8D illustrates a case where the calculated ratio is 110%. Under any of the conditions in FIGS. 8A to 8D, temperature of a refrigerant increases more on the downstream side, so that temperature of the second semiconductor device 71B (2nd) to the fifth semiconductor device 72A (5th) increases substantially proportionally. On the other hand, deviation of temperature of the sixth semiconductor device 73B (6th) from an approximate proportional straight line is small in a case where the ratio is 25% (FIG. 8A), but the deviation becomes remarkable in a case where the ratio is 50% or more (FIGS. 8B to 8D). This separation is caused by outflow of a refrigerant from the pin fin PF to the second flow path 100C as described above with reference to FIG. 6.

Therefore, also in the cooling device 150 according to the present embodiment as illustrated in FIG. 7, in a case where (L/W)×100%≥50% is satisfied, cooling performance of a heating element (semiconductor device 73B) on the most downstream side is more effectively exhibited. Note that in the example of FIG. 7, L=W, and the ratio is 100%.

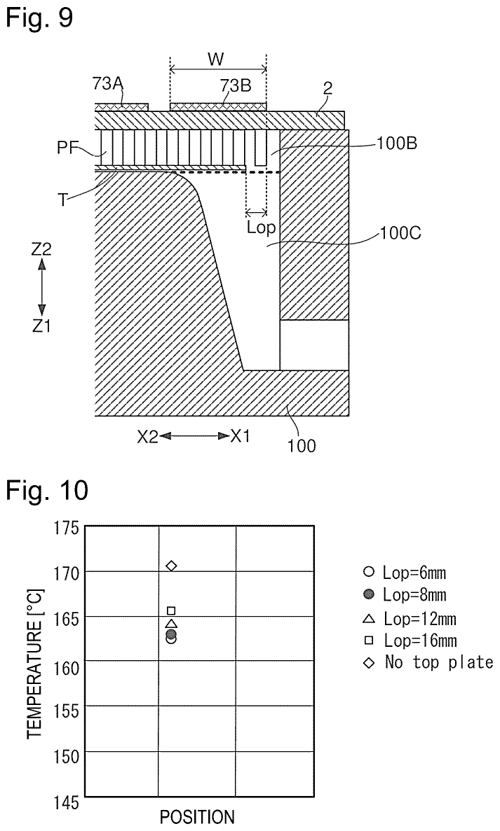

Further, simulation was performed on a model of a cooling device in which a top plate portion T is provided at an end portion on one side in the third direction of the pin fin PF as illustrated in FIG. 9. In the simulation, temperature of the semiconductor device 73B (heating element on the most downstream side) was simulated by changing a length Lop in the first direction from an end on one side in the first direction of the top plate portion T to an end on one side in the first direction of the semiconductor device 73B. The length Lop corresponds to a length of a region where the semiconductor device 73B is not covered by the top plate portion T.

FIG. 10 is a graph showing a result of the above simulation. In FIG. 10, the horizontal axis plots temperature at a position of the semiconductor device 73B. First direction width W of the semiconductor device 73B was set to 16 mm, and plotting was performed under a condition of a case where Lop=6 mm, 8 mm, 12 mm, and 16 mm, and the top plate portion T is not provided.

As illustrated in FIG. 10, there was almost no difference in temperature of the semiconductor device 73B up to Lop=8 mm, but when Lop=8 mm was exceeded, the temperature increased. That is, the temperature increased under a condition of Lop>W/2.

Based on such a result, in the cooling device 150 according to the present embodiment illustrated in FIG. 7, under a condition in which an area of a region where the top plate portion 503 does not overlap an arrangement region of a heating element (semiconductor device 73B) as viewed in the third direction is 50% or less of an area of the heating element, cooling performance of the heating element can be more effectively exhibited.

### <6. Variation of Heat Dissipation Member>

As in the model used in the simulation described above, the heat dissipation member may be configured by using, as a fin, a pin fin, for example, without limitation to a fin plate.

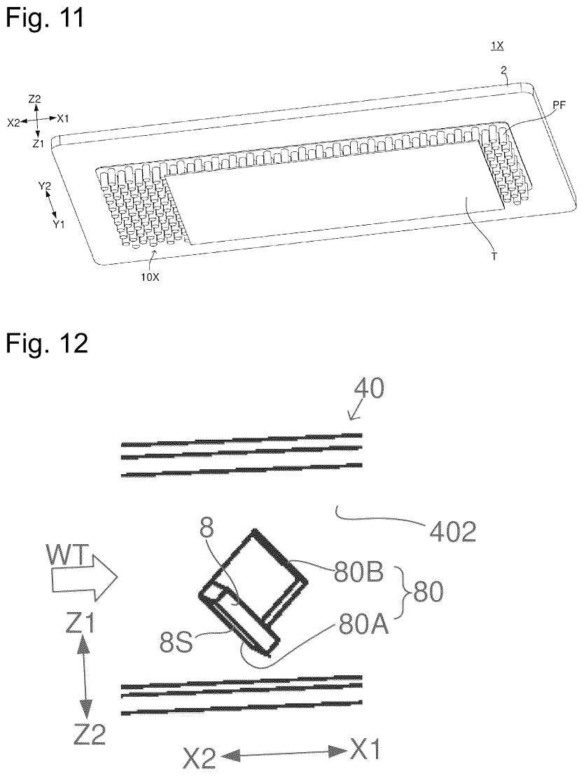

FIG. 11 is a perspective view illustrating a configuration example of a heat dissipation member using a pin fin. In a heat dissipation member 1X illustrated in FIG. 11, the pin fin PF projects in a columnar shape from the base portion 2 to one side in the third direction. A plurality of the pin fins PF constitute a heat dissipation fin portion 10x. The top plate portion T is provided at an end portion on one side in the third direction of the heat dissipation fin portion 10x. Also with a cooling device configured by installing the heat dissipation member 1X in a liquid cooling jacket, cooling performance of a heating element on the most downstream side arranged on another side in the third direction of the base portion 2 can be improved.

### <7. Spoiler>

As illustrated in FIG. 2, the fin plate FP is provided with a spoiler 8. Here, the spoiler 8 will be described in detail.

In the configuration illustrated in FIG. 2, a single spoiler in which only one of the spoiler 8 is provided is formed in the upstream side fin portion 30, and a double spoiler in which two of the spoilers 8 are provided is also formed in addition to the single spoiler in the center fin portion 40. In the downstream side fin portion 50, only the double spoiler is formed.

FIG. 12 is an enlarged perspective view illustrating a configuration example of a single spoiler. A through hole 80 penetrates the side wall portion 402 of the fin portion 40 in the second direction. The through hole 80 has a rectangular shape. The through hole 80 has a pair of facing sides 80A and 80B inclined to one side in the first direction and another side in the third direction. The side 80A is located further on another side in the first direction than the side 80B. The spoiler 8 is formed by being bent to one side in the second direction on the side 80A. The through hole 80 and the spoiler 8 can be formed by cutting and bending the side wall portion 402.

The spoiler 8 includes a facing surface 8S facing a direction in which the refrigerant WT flows, that is, one side in the first direction. The spoiler 8 has a function of preventing flow of the refrigerant WT by the facing surface 8S. Turbulent flow of the refrigerant WT is easily generated in the vicinity of the facing surface 8S, and cooling performance by the fin portion 30 can be improved. Further, the spoiler 8 is inclined to one side in the first direction and another side in the third direction. This makes it possible to guide the refrigerant WT to the base portion 2 side by the spoiler 8, and cooling performance can be improved.

Note that the single spoiler may have a configuration in which the spoiler 8 is provided on the side 80B side, in addition to the configuration illustrated in FIG. 12. Further, in the double spoiler, the spoiler 8 is provided on both the sides 80A and 80B.

As described above, the fin FP has at least one of the spoiler 8 projecting in the second direction from a side wall portion. Since turbulent flow is generated in the vicinity of the spoiler 8, cooling performance of the fin FP can be further improved.

Further, as illustrated in FIG. 2, the upstream side fin portion 30 is provided with two of the single spoilers, that is, two of the spoilers 8. In the center fin portion 40, one of the single spoiler and two of the double spoilers are provided, and five in total of the spoilers 8 are provided. In the downstream side fin portion 50, four of the double spoilers are provided, and eight in total of the spoilers 8 are provided.

That is, the number of the spoilers 8 included in each of a plurality of the fins 30, 40, and 50 arranged in the first direction increases toward one side in the first direction. By the above, cooling performance can be improved in the fin portion 50 on the downstream side where cooling performance is more required.

### <8. Others>

The embodiment of the present disclosure is described above. Note that the scope of the present disclosure is not limited to the above embodiment. The present disclosure can be implemented by making various changes to the above embodiment without departing from the gist of the invention. Further, the matters described in the above embodiment can be optionally combined together, as appropriate, as long as there is no inconsistency.

The present disclosure can be used for cooling various heating elements.

### REFERENCE SIGNS LIST

1, 1X heat dissipation member
2 base portion
3 upstream side fin group
3A, 3B end portion fin group
3C recessed portion
4 center fin group
5 downstream side fin group
8 spoiler
8S facing surface
10, 10X heat dissipation fin portion
21 surface on one side in third direction
22 surface on another side in third direction
30 upstream side fin portion
40 center fin portion
50 downstream side fin portion
61, 62 coupling fin
71A, 71B, 72A, 72B, 73A, 73B semiconductor device
80 through hole
80A, 80B side
100 liquid cooling jacket
100A inlet flow path
100B first flow path
100C second flow path
100C1 first inclined wall
100C2 second inclined portion
100D outlet flow path
100S1 top surface
100S2 surface on another side in third direction
150 cooling device
200 semiconductor module
301 bottom plate portion
302 side wall portion
303 top plate portion
304 notch portion
401 bottom plate portion
402 side wall portion
403 top plate portion
501 bottom plate portion
502 side wall portion
503 top plate portion
BT bottom plate portion
CS connection surface
FP1 first fin
FP2 second fin
PF pin fin
R facing region
T top plate portion
WT refrigerant

1. A cooling device comprising:
a liquid cooling jacket; and
a heat dissipation member installed in the liquid cooling jacket, wherein
the heat dissipation member includes:
a plate-shaped base portion that extends in a first direction along a direction in which a refrigerant flows and in a second direction orthogonal to the first direction, and has thickness in a third direction orthogonal to the first direction and the second direction;
at least one fin projecting from the base portion to one side in the third direction; and
a top plate portion provided in an end portion on one side in the third direction of the at least one fin,
the liquid cooling jacket includes:
a first flow path extending in the first direction in which the fin and the top plate portion are arranged; and
a second flow path connected to a downstream side of the first flow path and extending from the first flow path to one side in a third direction,
when viewed in the third direction, a connection surface connecting the second flow path and the first flow path and the top plate portion overlap each other, and
a heating element is arranged on a most downstream side on another side in the third direction of the base portion from a position where the second flow path starts to extend to one side in the third direction.

2. The cooling device according to claim 1, wherein
the fin includes:
a side wall portion having a flat plate shape, the side wall portion extending in the first direction and the third direction and having thickness in the second direction; and
the top plate portion bent in the second direction in an end portion on one side in the third direction of the side wall portion.

3. The cooling device according to claim 2, wherein
the fin has at least one spoiler projecting in the second direction from the side wall portion.

4. The cooling device according to claim 1, wherein
when a first direction distance from a position where the second flow path starts to extend to one side in the third direction to a position of an end on a downstream side of the heating element is L and a first direction width of the heating element is W, the following equation holds:
$$( L / W ) \times 100 \geq 50 \%$$

5. The cooling device according to claim 1, wherein
an area of a region where the top plate portion does not overlap an arrangement region of the heating element as viewed in the third direction is 50% or less of the heating element area.

6. The cooling device according to claim 1, wherein
when a downstream side where the refrigerant flows is defined as one side in the first direction,
the second flow path has at least one of:
a first inclined wall inclined toward one side in the first direction and toward one side in the third direction; and
a second inclined wall inclined toward another side in the first direction and toward one side in the third direction.

7. A cooling device comprising:
a liquid cooling jacket; and
a heat dissipation member, wherein
the heat dissipation member includes:
a plate-shaped base portion that extends in a first direction along a direction in which a refrigerant flows and in a second direction orthogonal to the first direction, and has thickness in a third direction orthogonal to the first direction and the second direction;
at least one fin projecting from one surface of the base portion to one side in the third direction; and
a top plate portion provided in an end portion on one side in the third direction of the at least one fin,
a heating element is arranged on another surface of the base portion,
the refrigerant flows from another side in the first direction to one side in the first direction through a flow path including the liquid cooling jacket and the heat dissipation member,
depth of the liquid cooling jacket increases in the third direction in a facing region facing the heating element in the third direction in a downstream side region of the flow path, and
the top plate portion is provided in at least a part of the facing region.

8. A heat dissipation member installed in a liquid cooling jacket, the heat dissipation member comprising:
a plate-shaped base portion that extends in a first direction along a direction in which a refrigerant flows and in a second direction orthogonal to the first direction, and has thickness in a third direction orthogonal to the first direction and the second direction;
at least one fin projecting from the base portion to one side in the third direction; and
a top plate portion provided in an end portion on one side in the third direction of the at least one fin, wherein
the liquid cooling jacket includes:
a first flow path extending in the first direction in which the fin and the top plate portion are arranged; and
a second flow path connected to a downstream side of the first flow path and extending from the first flow path to one side in a third direction,
when viewed in the third direction, a connection surface connecting the second flow path and the first flow path and the top plate portion overlap each other, and
a heating element is arranged on a most downstream side on another side in the third direction of the base portion from a position where the second flow path starts to extend to one side in the third direction.

9. A semiconductor module comprising:
the heat dissipation member according to claim 8; and
a semiconductor device as the heating element.
